(19) United States
(12) Patent Application Publication
(10) Pub. No.: US 2010/0207255 A1
(43) Pub. Date: Aug. 19, 2010

(54) Shield for an intergrated circuit

(75) Inventors: Marco Fenoglio, Torino (IT); Daniele Marziantonio, San Maurizio Canavese (IT); Michele Minen, Udine (IT)

Correspondence Address: The Watson Intellectual Property Group, PLC;[Motorola], 3133 Highland Drive, Suite 200, Hudsonville, MI, 49426, US

(73) Assignee: Motorola, Inc.

(21) Appl. No.: 12/383,075

(22) Filed: Mar. 19, 2009

(30) Foreign Application Priority Data
Feb. 17, 2009 (IT) RM2009A000070

(51) Int. Cl. H01L 23/552

(52) U.S. Cl. 257/659; 361/816; 257/E23.114

(57) ABSTRACT

A shield for an integrated circuit comprising an upper wall and a side wall assembly. The upper wall includes a top surface, a bottom surface and a perimeter. The side wall assembly depends from the perimeter of the upper wall. The side wall assembly has a proximal end, a distal end, an inner surface and an outer surface. The distal end defines a lower edge. At least a portion of the side wall assembly includes a plurality of surface variations along a length thereof, to, in turn, define a lower edge of the side wall assembly having a non-linear configuration. Such a non-linear configuration increases the rigidity of the shield.

This application claims priority from Italian Patent Application Number RM2009A000070 filed Feb. 17, 2009 entitled “Shield for an Integrated Circuit,” the entire specification of which is hereby incorporated by reference.

### BACKGROUND OF THE DISCLOSURE

1. Field of the Disclosure

The disclosure relates in general to a electrical shield, and more particularly, to a shield for an integrated circuit.

2. Background Art

Common to electrical assemblies is the shield which is used to isolate sensitive components on a circuit board assembly (i.e., a PCB). Commonly such shields comprise a metal or metallized member which has a substantially planar top wall with a substantially planar side wall extending from each edge of the top wall. The distal ends of such walls may include feet or flanges which assist with the soldering of the shield to the underlying circuit board assembly.

Generally, the shields lack strength when the PCB is subjected to mechanical loading, such as bending loads, torsional loads and plane loads. In such situations, the shield may be compromised. A compromise to the shield may, in turn, compromise the ability of the shield to isolate sensitive components.

Additionally, where a shield can be configured with adequate strength, the shield can be utilized to further enhance the stiffness of the resulting circuit board in under mechanical loading. Such a configuration can decrease stresses and strains relative to the integrated circuit therebelow as well as in the interface between the integrated circuits and the underlying circuit board.

### SUMMARY OF THE DISCLOSURE

The disclosure is directed to a shield for an integrated circuit, and an electrical assembly having a circuit board with an integrated circuit, wherein the shield is disposed over and around the integrated circuit.

The shield comprises an upper wall and a side wall assembly. The upper wall includes a top surface, a bottom surface and a perimeter. The side wall assembly depends from the perimeter of the upper wall. The side wall assembly has a proximal end, a distal end, an inner surface and an outer surface. The distal end defines a lower edge. At least a portion of the side wall assembly includes a plurality of surface variations along a length thereof, to, in turn, define a lower edge of the side wall assembly having a non-linear configuration. Such a non-linear configuration increases the rigidity of the shield.

In an exemplary embodiment, the plurality of surface variations extend from the proximal end of the side wall to the distal end of the side wall. Additionally, the perimeter of the upper wall comprises a plurality of substantially linear edges.

In an exemplary embodiment, the non-linear configurations comprise a plurality of peaks with outwardly concave circular segments positioned therebetween in a side by side orientation. The outwardly concave circular segments may be substantially identical to each other.

In another exemplary embodiment, the non-linear configurations comprise a plurality of peaks with one of the group consisting of outwardly concave circular segments, outwardly convex circular segments, intersecting linear segments, and combinations thereof between the plurality of peaks.

In another exemplary embodiment, the upper wall includes a plurality of substantially linear side edges that collectively define the perimeter. The side wall assembly comprises a plurality of side walls depending from each of the plurality of linear side edges. Each of the side walls has a plurality of indentations along a length thereof, to, in turn, define a lower edge of the side wall assembly having a curved configuration.

In an exemplary embodiment, the side wall has a nominal thickness and the surface variations define an overall thickness of the side wall between the proximal end and the distal end. The overall thickness of the side wall increases between the proximal end and the distal end.

In an exemplary embodiment, the overall thickness of the side wall may be greatest at the lower edge thereof.

In an exemplary embodiment, the overall thickness of the side wall is at least 20% greater than the nominal thickness of the side wall.

In an exemplary embodiment, the upper wall and the side walls comprise a single integrated metal member. The side walls are bent in a downward direction from the upper wall and the surface variations formed therein.

The shield can be incorporated into an electrical assembly. The electrical assembly includes a circuit board with a first surface and a second surface. An integrated circuit is positioned on one of the first and second surfaces and coupled to the circuit board (i.e., through soldering, wire wrapping or the like). It will be understood that the upper wall and the side wall assembly of the shield together define a cavity. The shield is installed such that the integrated circuit falls within the cavity of the shield. The shield is then coupled to the underlying circuit board (i.e., again through the use of solder or the like).

### BRIEF DESCRIPTION OF THE DRAWINGS

The disclosure will now be described with reference to the drawings wherein:

FIG. 1 of the drawings comprises a top plan view of an electrical assembly showing a shield of the present disclosure disposed over an integrated circuit and coupled to an underlying circuit board;

FIG. 2 of the drawings comprises a cross-sectional view of the electrical assembly taken about lines 2-2 of FIG. 1;

FIG. 3 of the drawings comprises a perspective view of the shield of the present disclosure;

FIG. 4 of the drawings comprises a plurality of different non-linear configurations which may be found of the lower edge of the side wall assembly; and

FIG. 5 of the drawings comprises a partial cross sectional view of the electrical assembly about lines 5-5 of FIG. 1, showing, in particular, the nominal thickness and the overall thickness of the shield and the coupling of the shield to the underlying circuit board.

### DETAILED DESCRIPTION OF THE DISCLOSURE

While this invention is susceptible of embodiment in many different forms, there is shown in the drawings and described herein in detail a specific embodiment with the understanding that the present disclosure is to be considered as an exemplification and is not intended to be limited to the embodiment illustrated.

It will be understood that like or analogous elements and/or components, referred to herein, may be identified throughout the drawings by like reference characters. In addition, it will be understood that the drawings are merely schematic representations of the invention, and some of the components may have been distorted from actual scale for purposes of pictorial clarity.

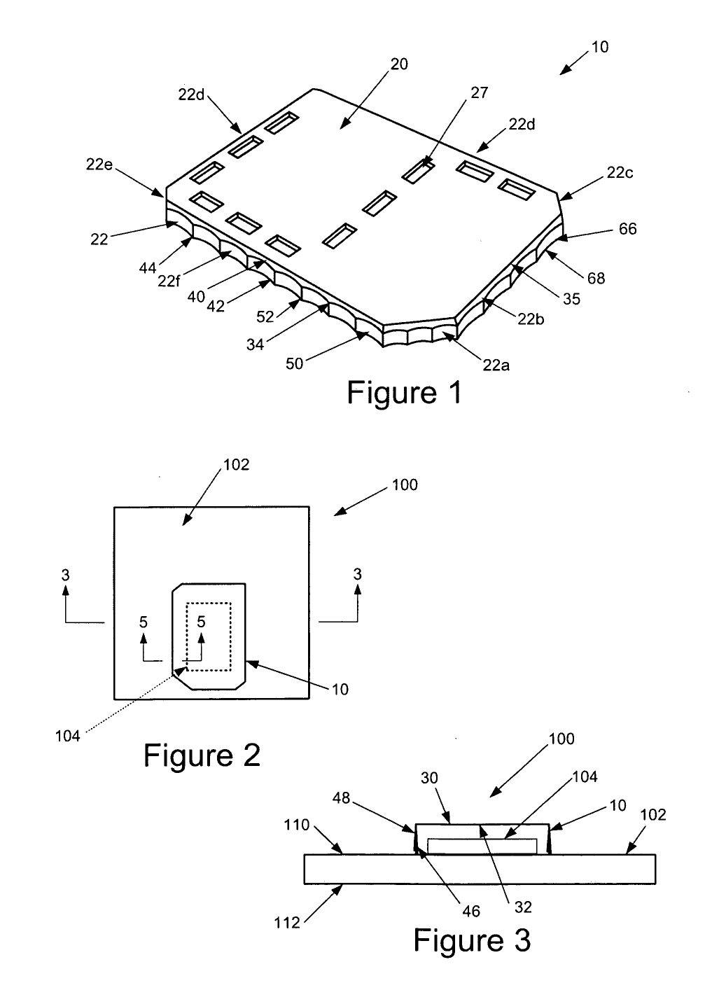

Referring now to the drawings and in particular to FIG. 1, the shield for an integrated circuit is shown generally at 10. With reference to FIGS. 2 and 3, the shield 10 is configured for shielding an integrated circuit (IC) 104 of circuit board 102 of electrical assembly 100. Such an assembly may be found in many different devices. For example, such an assembly 100 may be found in a mobile telephone. It will be understood that the reference to a mobile phone is purely for illustrative purposes and the shield of the disclosure is certainly usable and compatible with any number of different structures and devices.

The shield 10 is shown in FIG. 1 as comprising upper wall 20 and side wall assembly 22, which together define a cavity 33 (FIG. 3). The upper wall, 20 includes top surface 30, bottom surface 32 and outer perimeter 34. The outer perimeter comprises a number of segments, or edges 35. In the embodiment shown, these segments comprise a plurality of substantially linear edges to define a substantially rectangular upper wall with certain corners being chamfered. The upper wall 20 comprises a substantially uniform thickness and is substantially planar in typical usages. Of course, variations are contemplated. In certain embodiments, openings, such as openings 37 may extend through the upper wall.

With reference to FIG. 1, the side wall assembly 22 includes a plurality of side walls 22a through 22g. The side wall assembly 22 includes proximal end 40 and distal end 42. The distal end 42 terminates with lower edge 44. Furthermore, the side wall assembly includes inner surface 46 and outer surface 48. The inner and outer surfaces combine to define a plurality of surface variations 50. As these surface variations extend from the proximal end to the distal end, at the lower edge 44, such surface variations result in a non linear configuration 52 of the lower edge 44. In the embodiment shown, the length and width of the upper wall 20 is substantially larger than the height of the side wall assembly (i.e., the distance between the proximal end and the distal end).

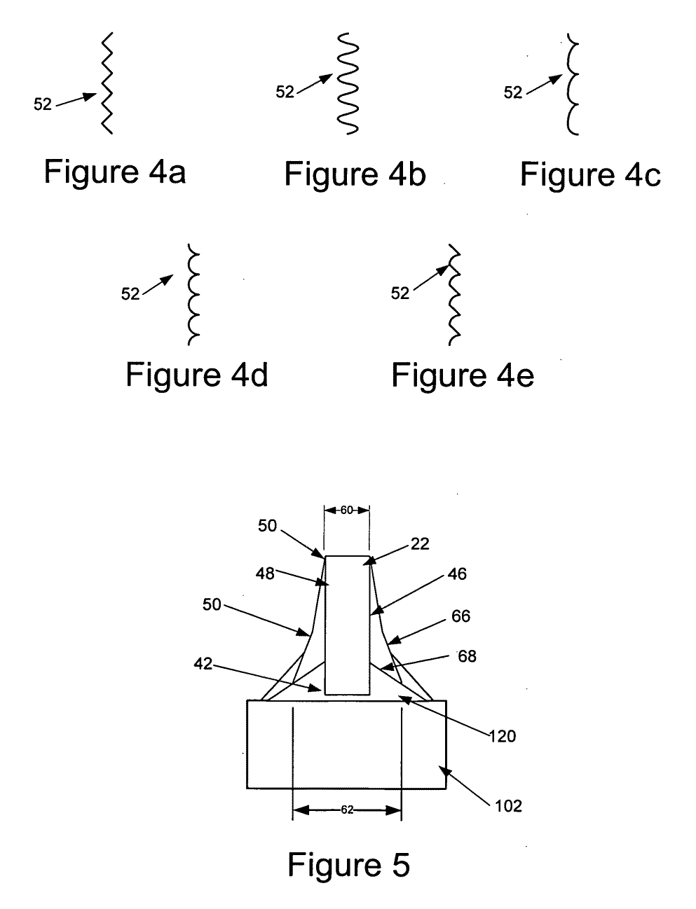

Depending on the particular configuration, the non-linear configuration may comprise a plurality of peaks, such as peak 66 with outwardly concave segments 68 therebetween positioned in a side by side orientation. In the embodiment shown, and while not required, each of the outwardly concave segments are substantially identical in configuration. In other embodiments, these segments may be identical or dimensionally different. In other embodiments, there may be a plurality of outwardly convex or concave segments that are curved or that result from a plurality of linear segments, or a combination of both. For illustrative purposes, a number of non-linear configurations of lower edge 44 are shown in FIGS. 4a through 4e. It will be understood that these are for illustrative purposes only and are not to be deemed limiting. Specifically, FIG. 4a shows a plurality of linear segments. FIG. 4b shows a plurality of substantially uniform continuous curves (such as a sinusoidal curve). FIG. 4c shows a non symmetrical repeating plurality of curves between peaks. FIG. 4d shows a symmetrical repeating plurality of curves between peaks. FIG. 4e shows linear segments coupled with curves to between peaks.

In the embodiments shown, the segments 35 of the perimeter 34 of the upper wall 20 are generally linear, and the side wall assembly wall itself has a nominal thickness 60. As a result, at the proximal end 40 of the side wall assembly 22, the side wall assembly is substantially planar. The surface variations 50 tend to increase in amplitude between the proximal end 40 and the distal end 42. The side wall assembly, due to the surface variations 50 increases in width, such that it defines an overall thickness 62 in addition to the wall thickness itself, or the nominal thickness 60. Generally, the overall thickness of the side wall assembly is at least 20% greater than the nominal thickness 60. It will be understood that as the overall thickness increases, the strength of the sidewall assembly and increases, to a point. In the embodiment shown, the overall thickness is almost three times that of the nominal thickness. Of course, the nominal thickness can be varied for different applications as needed without departing from the scope of the present invention.

In use, and with reference to FIGS. 2 and 3, an electrical assembly 100 includes circuit board 102 and integrated circuit 104. The circuit board 102 includes first surface 110 and second surface 112 opposite of first surface 110. The circuit board may comprise, for example a PCB, or the like. The integrated circuit 104 is positioned on the first surface 110 and the leads thereof are electrically coupled to the circuit board (i.e., through, for example, soldering).

With reference to FIG. 3, the shield 10 is then positioned over the integrated circuit 104 and then electrically coupled to the first surface 110 of the circuit board 102. In the embodiment shown, the shield is coupled to the circuit board 102 with solder, such as solder 120 shown in FIG. 5.

It has been found that with the shield of the present configuration, the shield is stiffer and provides benefits under mechanical loading (including shock loading). Through testing, for example, a fifteen percent reduction in strain has been demonstrated. Of course, depending on the particular configuration, the reduction in strain may be greater than 15%. Additionally, not only is the shield stiffer under mechanical loading (thereby better protecting the underlying integrated circuit), but the overall circuit board, i.e., the portions of the board outside of those covered by the shield also exhibit a reduction in strain under mechanical loading. Furthermore, the configuration of the side wall assemblies of the shield of the present disclosure, additionally retain more solder paste which aids in the attachment of the shield to the underlying circuit board.

The foregoing description merely explains and illustrates the invention and the invention is not limited thereto except insofar as the appended claims are so limited, as those skilled in the art who have the disclosure before them will be able to make modifications without departing from the scope of the invention.

What is claimed is:

1. A shield for an integrated circuit comprising:
an upper wall having a top surface, a bottom surface and a perimeter;
a side wall assembly depending from the perimeter of the upper wall, the side wall assembly having a proximal end, a distal end, an inner surface and an outer surface, the distal end defining a lower edge;
wherein at least a portion of the side wall assembly includes a plurality of surface variations along a length thereof, to, in turn, define a lower edge of the side wall assembly having a non-linear configuration.

2. The shield of claim 1 wherein the plurality of surface variations extend from the proximal end of the side wall to the distal end of the side wall, wherein the perimeter of the upper wall comprises a plurality of substantially linear edges.

3. The shield of claim 2 wherein the non-linear configurations comprise a plurality of peaks with outwardly concave circular segments positioned therebetween in a side by side orientation.

4. The shield of claim 3 wherein the outwardly concave circular segments are substantially identical to each other.

5. The shield of claim 2 wherein the non-linear configurations comprise a plurality of peaks with one of the group consisting of outwardly concave circular segments, outwardly convex circular segments, intersecting linear segments, and combinations thereof between the plurality of peaks.

6. The shield of claim 1 wherein the upper wall includes a plurality of substantially linear side edges defining the perimeter, the side wall assembly comprises a plurality of side walls depending from each of the plurality of linear side edges, each of the side walls having a plurality of indentations along a length thereof, to, in turn, define a lower edge of the side wall assembly having a curved configuration.

7. The shield of claim 1 wherein the side wall has a nominal thickness and the surface variations define an overall thickness of the side wall between the proximal end and the distal end, the overall thickness of the side wall increases between the proximal end and the distal end.

8. The shield of claim 6 wherein the overall thickness of the side wall is greatest at the lower edge thereof.

9. The shield of claim 6 wherein the overall thickness of the side wall is at least 20% greater than the nominal thickness of the side wall.

10. The shield of claim 1 wherein the upper wall and the side walls comprise a single integrated metal member with the side walls being bent in a downward direction from the upper wall and the surface variations formed therein.

11. An electrical assembly comprising:
a circuit board having a first surface and a second surface;
at least one integrated circuit positioned on one of the first surface and the second surface of the circuit board and coupled thereto; and
a shield defining a cavity extending over the at least one integrated circuit so as to position the integrated circuit within the cavity, the shield comprising:
an upper wall having a top surface, a bottom surface and a perimeter;
a side wall assembly depending from the perimeter of the upper wall, the side wall assembly having a proximal end, a distal end, an inner surface and an outer surface, the distal end defining a lower edge;
wherein at least a portion of the side wall assembly includes a plurality of surface variations along a length thereof, to, in turn, define a lower edge of the side wall assembly having a non-linear configuration, and wherein the side wall assembly is coupled to the circuit board.

12. The shield of claim 11 wherein the plurality of surface variations extend from the proximal end of the side wall to the distal end of the side wall, wherein the perimeter of the upper wall comprises a plurality of substantially linear edges.

13. The shield of claim 12 wherein the non-linear configurations comprise a plurality of peaks with outwardly concave circular segments positioned therebetween in a side by side orientation.

14. The shield of claim 13 wherein the outwardly concave circular segments are substantially identical to each other.

15. The shield of claim 12 wherein the non-linear configurations comprise a plurality of peaks with one of the group consisting of outwardly concave circular segments, outwardly convex circular segments, intersecting linear segments, and combinations thereof between the plurality of peaks.

16. The shield of claim 11 wherein the upper wall includes a plurality of substantially linear side edges defining the perimeter, the side wall assembly comprises a plurality of side walls depending from each of the plurality of linear side edges, each of the side walls having a plurality of indentations along a length thereof, to, in turn, define a lower edge of the side wall assembly having a curved configuration.

17. The shield of claim 11 wherein the side wall has a nominal thickness and the surface variations define an overall thickness of the side wall between the proximal end and the distal end, the overall thickness of the side wall increases between the proximal end and the distal end.

18. The shield of claim 16 wherein the overall thickness of the side wall is greatest at the lower edge thereof.

19. The shield of claim 16 wherein the overall thickness of the side wall is at least 20% greater than the nominal thickness of the side wall.

20. The shield of claim 11 wherein the upper wall and the side walls comprise a single integrated metal member with the side walls being bent in a downward direction from the upper wall and the surface variations formed therein.
